(19) United States
(12) Patent Application Publication
(10) Pub. No.: US 2026/0223453 A1
(43) Pub. Date: Jul. 30, 2026

(54) INTEGRATED CIRCUIT DEVICES INCLUDING CONTACT POWER RAIL STRUCTURES FOR THREE-DIMENSIONAL STACKED FIELD-EFFECT TRANSISTOR STRUCTURES AND METHODS OF FORMING THE SAME

(71) Applicant: Samsung Electronics Co., Ltd., Suwon-si (KR)

(72) Inventors: Jinyoung Lim, Schenectady, NY (US); Jongmin Shin, Niskayuna, NY (US); Beomjin Park, Clifton Park, NY (US); Hyo Jong Shin, Mechanicville, NY (US); YoungGook Park, Resselaer, NY (US); Kang-ill Seo, Springfield, VA (US)

(21) Appl. No.: 19/357,424

(22) Filed: Oct. 14, 2025

Related U.S. Application Data
(60) Provisional application No. 63/751,029, filed on Jan. 29, 2025.

(51) Int. Cl. H10D 84/85; H10D 84/01

(52) U.S. Cl. CPC H10D 84/856; H10D 84/0186; H10D 84/851

(57) ABSTRACT

An integrated circuit device includes a substrate, a lower transistor on a first surface of the substrate, an upper transistor on the lower transistor, the upper transistor including an upper gate structure extending in a first lateral direction parallel to the first surface of the substrate and an upper source/drain region adjacent to the upper gate structure in a second lateral direction orthogonal to the first lateral direction, a backside power delivery network (BSPDN) structure on a second surface of the substrate opposite the first surface, the BSPDN structure including a backside power rail, and a contact power rail structure that electrically connects the upper source/drain region to the backside power rail. The contact power rail structure overlaps the upper gate structure in the first lateral direction.

### RELATED APPLICATIONS

The present application claims the benefit of U.S. Provisional Patent Application Serial No. 63/751,029, entitled “CONTACT POWER RAIL FOR 3D-STACKED FIELD-EFFECT TRANSISTOR DEVICE,” filed on January 29, 2025, with the United States Patent and Trademark Office, the disclosure of which is hereby incorporated by reference herein in its entirety.

### TECHNICAL FIELD

The present disclosure generally relates to the field of integrated circuit devices and, more particularly, to integrated circuit devices including three-dimensional (3D) transistor stacks and methods of forming the same.

### BACKGROUND

Integrated circuit devices may include various active components formed on a frontside of the device. For example, transistors may be formed on the frontside of an integrated circuit device, semiconductor chip, or wafer (generally referred to herein as an integrated circuit device). These transistors may have various structures such as, for example, two-dimensional (2D) planar structures, fin field-effect transistor (FinFET) structures, gate-all-around (GAA) structures, multi-bridge channel FET (MBCFET^{TM}) structures, and/or stacked transistor structures (e.g., three-dimensional stacked field-effect transistor (3DSFET) structures).

Integrated circuit devices may receive power and data signals from one or more external sources (e.g., a power source and a data source). Some integrated circuit devices may receive power and data signals via frontside conductive structures, which may provide power delivery networks. For example, an integrated circuit device may include a frontside power delivery network (FSPDN) structure having one or more components that are formed during the back-end-of-line (BEOL) portion of device fabrication, and conductive structures for data signals may be on the same side of the integrated circuit device as the FSPDN structure. More recently, backside power delivery network (BSPDN) structures, in which a backside of an integrated circuit device is used as a power delivery network, have also been proposed.

### SUMMARY

Example embodiments of the present disclosure provide integrated circuit devices that include a transistor stack of a lower transistor and an upper transistor, and a backside power delivery network (BSPDN) structure electrically connected to the transistor stack. A contact power rail structure may be used to electrically connect an upper source/drain region of the upper transistor to a backside power rail of the BSPDN structure. Pursuant to example embodiments herein, the contact power rail structure may have a line (or rail) shape in a plan view. For example, the line (or rail) shape of the contact power rail structure may increase its width and cross-sectional area, as well as its contact area with the backside power rail. The configuration of the contact power rail structure may therefore advantageously reduce contact resistance with the backside power rail, mitigate current crowding by distributing current more uniformly across a larger area, and reduce a voltage drop during backside power delivery to the upper transistor.

An integrated circuit device, according to some embodiments herein, may include a substrate, a lower transistor on a first surface of the substrate, an upper transistor on the lower transistor, the upper transistor comprising an upper gate structure extending in a first lateral direction parallel to the first surface of the substrate and an upper source/drain region adjacent to the upper gate structure in a second lateral direction orthogonal to the first lateral direction, a backside power delivery network (BSPDN) structure on a second surface of the substrate opposite the first surface, the BSPDN structure comprising a backside power rail, and a contact power rail structure that electrically connects the upper source/drain region to the backside power rail, wherein the contact power rail structure overlaps the upper gate structure in the first lateral direction.

An integrated circuit device, according to some embodiments herein, may include a substrate, a lower transistor on a first surface of the substrate, an upper transistor on the lower transistor, the upper transistor comprising an upper gate structure extending in a first lateral direction parallel to the first surface of the substrate and an upper source/drain region adjacent to the upper gate structure in a second lateral direction orthogonal to the first lateral direction, a backside power delivery network (BSPDN) structure on a second surface of the substrate opposite the first surface, the BSPDN structure comprising a backside power rail, and a contact power rail structure that electrically connects the upper source/drain region to the backside power rail, wherein a width of the contact power rail structure in the second lateral direction is greater than a width of the upper source/drain region in the second lateral direction.

A method of forming an integrated circuit device, according to some embodiments herein, may include forming a lower channel layer and an upper channel layer, the lower and upper channel layers spaced apart in a vertical direction, forming a lower source/drain region on a side surface of the lower channel layer and an upper source/drain region on a side surface of the upper channel layer, forming a contact power rail structure that overlaps at least one of the lower channel layer or the upper channel layer in a first lateral direction orthogonal to the vertical direction, and forming a backside power delivery network (BSPDN) structure comprising a backside power rail on a lower surface of the contact power rail structure, wherein the contact power rail structure electrically connects the upper source/drain region to the backside power rail.

Other devices, apparatuses, and/or methods according to example embodiments will become more apparent to one of ordinary skill in the art upon review of the following drawings and detailed description. It is intended that all such additional embodiments, in addition to any and all combinations of the above embodiments, be included within this description, be within the scope of the present disclosure, and be protected by the accompanying claims.

### BRIEF DESCRIPTION OF THE DRAWINGS

FIG. 1A is a schematic block diagram illustrating a transistor stack of an integrated circuit device according to some embodiments.

FIG. 1B is a schematic plan view illustrating an integrated circuit device according to some embodiments.

FIG. 1C is a schematic cross-sectional view taken along line A-A’ of FIG. 1B.

FIG. 1D is a schematic cross-sectional view taken along line B-B’ of FIG. 1B.

FIGS. 2A and 2B are schematic plan views illustrating backside power rails of integrated circuit devices according to some embodiments.

FIGS. 3A, 3B, 3C, 3D, 3E, 3F, and 3G are schematic cross-sectional views illustrating a method of forming an integrated circuit device according to some embodiments.

FIG. 4 is a flowchart illustrating a method of forming an integrated circuit device according to some embodiments.

FIG. 5 is a schematic plan view illustrating an integrated circuit device according to a comparative example.

### DETAILED DESCRIPTION

Example embodiments are described herein with reference to the accompanying drawings, which may include plan and cross-section illustrations that are schematic illustrations of idealized embodiments (and intermediate structures). The sizes and relative sizes of layers and regions may be exaggerated for clarity. Additionally, variations from the shapes of the illustrations as a result, for example, of manufacturing techniques and/or tolerances, are to be expected. The same reference numerals may be used to refer to the same or similar elements in various embodiments.

Integrated circuit devices may include stacked transistor structures (e.g., three-dimensional stacked field-effect transistor (3DSFET) structures), in which a lower transistor and an upper transistor are vertically stacked on a frontside of a substrate. Stacked transistor structures (i.e., transistor stacks) may improve integration density and enable continued scaling by vertically integrating transistors, thereby improving the performance and power efficiency of an integrated circuit device.

Integrated circuit devices may also include backside power delivery network (BSPDN) structures, in which a backside of a substrate is used as a power delivery network. In a BSPDN structure, a backside power rail may be formed on the backside of the device, rather than on the frontside thereof. As such, the backside power rail may be on a side of the substrate that is opposite from the active components (e.g., transistors). In some integrated circuit devices, upper structures including conductive elements for data signals may be on the frontside of the device, and thus the BSPDN structure and the conductive elements for the data signals may be on opposite sides of the substrate. BSPDN structures may improve, for example, power rail effectiveness, voltage drop (i.e., IR drop), high power delivery performance, and scaling of standard cell height.

Some integrated circuit devices may include stacked transistor structures and BSPDN structures. For these devices, it may be advantageous to configure the BSPDN structure to power both the lower and upper transistors of the transistor stack. For example, backside power delivery to the lower and upper transistors may allow a frontside power delivery network (FSPDN) structure (i.e., a frontside power track) to be omitted, thereby increasing integration density and reducing standard cell height. Despite these advantages, a contact structure electrically connecting the upper transistor to the BSPDN structure may exhibit high resistance. For example, the transistor stack may result in the contact structure having a relatively tall height (or thickness) to connect between the upper transistor and the BSPDN structure, resulting in a longer electrical path and increased resistance. The contact structure may also have a relatively narrow width and a high aspect ratio, which may present challenges during fabrication of the contact structure and may also lead to increased resistance. The resistance of the contact structure may cause a higher voltage drop during backside power delivery to the upper transistor, thereby reducing the performance and reliability of an integrated circuit device.

Pursuant to example embodiments herein, integrated circuit devices are provided that include contact power rail structures having a line (or rail) shape in a plan view. The line (or rail) shape of the contact power rail structure may increase its width and cross-sectional area, as well as its contact area with a backside power rail. The configuration of the contact power rail structure may therefore advantageously reduce contact resistance with the backside power rail, mitigate current crowding by distributing current more uniformly across a larger area, and reduce a voltage drop during backside power delivery to an upper transistor. Accordingly, the performance and reliability of an integrated circuit device may be improved.

Some examples of embodiments of the present disclosure are described in greater detail hereinafter with reference to the attached figures.

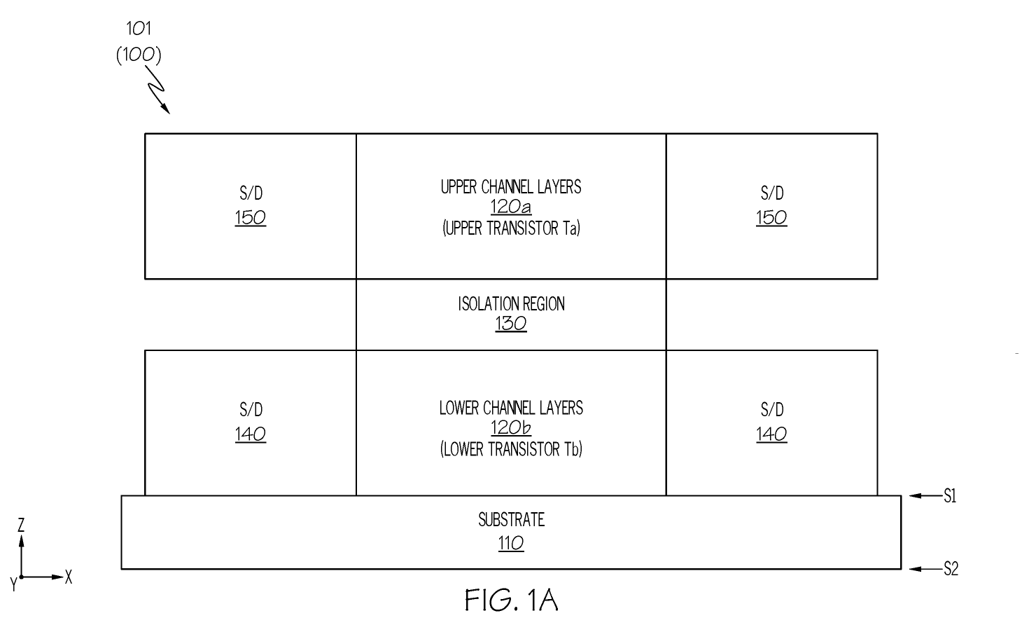

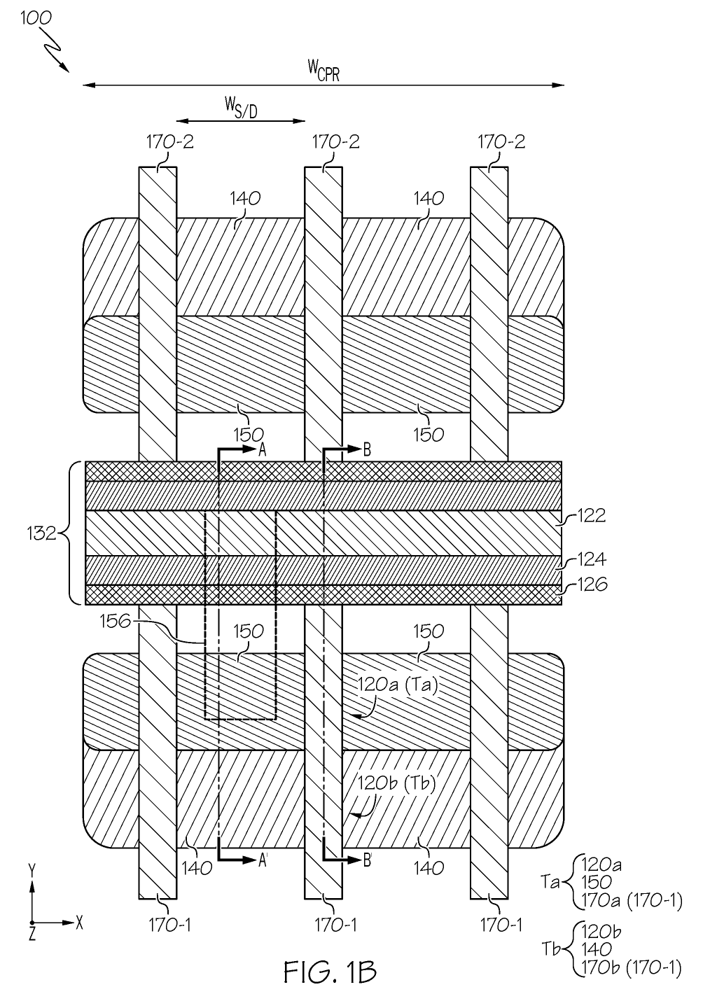

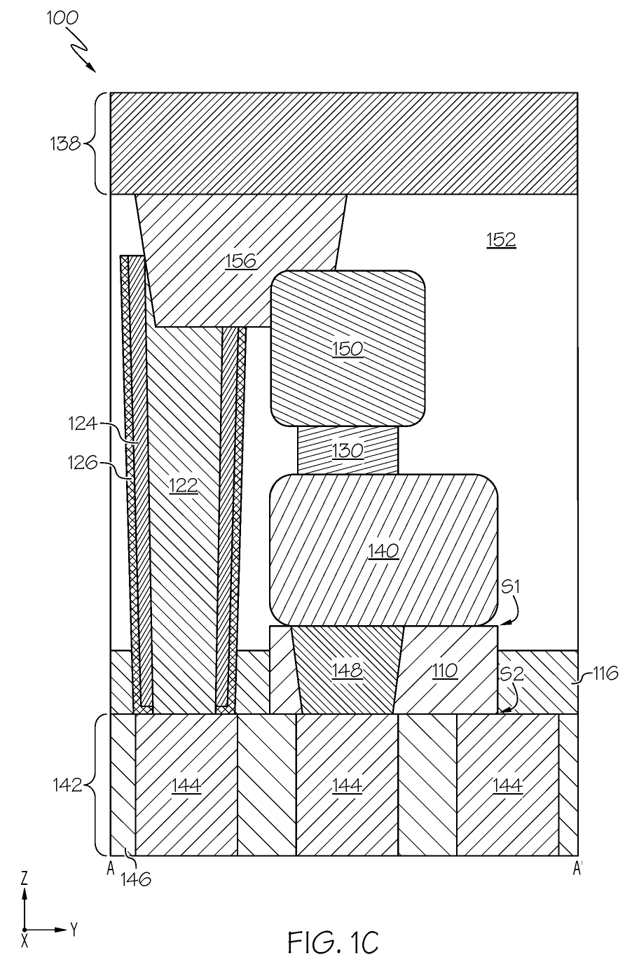

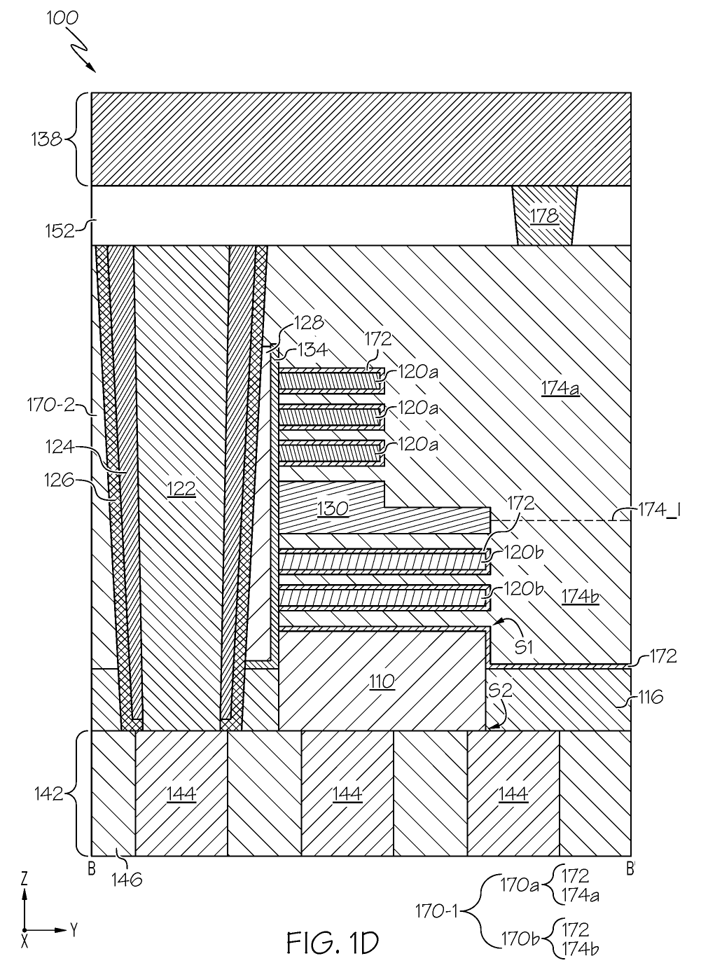

FIG. 1A is a schematic block diagram illustrating a transistor stack of an integrated circuit device according to some embodiments.

Referring to FIG. 1A, an integrated circuit device 100 includes a substrate 110 and a transistor stack 101 on a first surface S1 (i.e., a frontside) of the substrate 110. The substrate 110 may extend in a first direction Y (which may also be referred to as a first lateral direction) and a second direction X (which may also be referred to as a second lateral direction). The first direction Y and the second direction X may be substantially parallel to the first surface S1 and/or a second surface S2 (i.e., a backside) of the substrate 110. For example, the first direction Y may intersect the second direction X. In some embodiments, the first direction Y may be orthogonal (or perpendicular) to the second direction X. As used herein, the first surface S1 and the second surface S2 of the substrate 110 may also be referred to as an “upper surface” and a “lower surface” of the substrate 110, respectively.

The first surface S1 of the substrate 110 is opposite the second surface S2 in a third direction Z (which may also be referred to as a vertical direction). The third direction Z may be substantially perpendicular to the first surface S1 and/or the second surface S2 of the substrate 110. For example, the third direction Z may intersect the first direction Y and the second direction X.

In some embodiments, the substrate 110 may include or may be formed of insulating material(s) and may thus also be referred to as a backside insulating structure. For example, insulating material(s) included in the substrate 110 may help reduce parasitic capacitance and/or leakage current paths associated with a backside contact structure 148 (described in greater detail below). In some embodiments, the substrate 110 may include silicon oxide, silicon oxynitride, silicon nitride, silicon carbonitride, silicon boron nitride, silicon boron carbonitride, and/or a low-k dielectric material. The low-k dielectric material may include, for example, fluorine-doped silicon oxide, organosilicate glass, carbon-doped oxide, porous silicon dioxide, porous organosilicate glass, spin-on organic polymeric dielectrics and/or spin-on silicon based polymeric dielectrics. Although the substrate 110 may include insulating material(s) in some embodiments, the present disclosure is not limited thereto. In some embodiments, the substrate 110 may include or may be formed of semiconductor material(s), for example, Si, Ge, SiGe, GaP, GaAs, SiC, SiGeC and/or InP. For example, the substrate 110 may be insulating layer(s), a bulk substrate (e.g., a bulk silicon wafer) and/or a semiconductor-on-insulator (SOI) substrate.

The transistor stack 101 includes a lower transistor Tb having a stack of lower semiconductor channel layers 120b, and an upper transistor Ta having a stack of upper semiconductor channel layers 120a. The channel layers 120a, 120b may include, for example, semiconductor material(s) (e.g., Si, Ge, SiGe, GaP, GaAs, SiC, SiGeC and/or InP). In some embodiments, the channel layers 120a, 120b may be nanosheets that may have a thickness, for example, in a range of about 1 nm to about 100 nm in the third direction Z, or may be nanowires that may have a circular or elliptical cross-section with a diameter, for example, in a range of about 1 nm to about 100 nm.

The lower transistor Tb and the upper transistor Ta are vertically stacked in the third direction Z on the substrate 110. The lower transistor Tb is on the substrate 110 and may be between, in the third direction Z, the upper transistor Ta and the substrate 110. For example, the upper transistor Ta may be on the lower transistor Tb and may overlap the lower transistor Tb in the third direction Z. As used herein, “an element A overlaps an element B in a direction” (or similar language) means that there is at least one straight line that extends in the direction and intersects both the elements A and B. In some embodiments, the lower transistor Tb and the upper transistor Ta may be field-effect transistors (FETs) that are vertically stacked. As such, the transistor stack 101 (including the upper and lower transistors Ta, Tb) may also be referred to herein as a “three-dimensional stacked field-effect transistor (3DSFET) structure.”

The transistor stack 101 may also include an isolation region 130, such as a middle dielectric isolation (MDI) region. The isolation region 130 may, in some embodiments, serve as a spacer between the upper and lower transistors Ta, Tb. The isolation region 130 may thus also be referred to as a spacer.

The plurality of lower channel layers 120b of the lower transistor Tb are between, in the second direction X, a pair of lower source/drain (S/D) regions 140 that are electrically connected to the lower channel layers 120b. Likewise, the plurality of upper channel layers 120a of the upper transistor Ta are between, in the second direction X, a pair of upper source/drain regions 150 that are electrically connected to the upper channel layers 120a. The lower source/drain regions 140 may be between, in the third direction Z, the upper source/drain regions 150 and the substrate 110. Side surfaces of the lower channel layers 120b may contact (e.g., may be directly on) the lower source/drain regions 140, and side surfaces of the upper channel layers 120a may contact (e.g., may be directly on) the upper source/drain regions 150.

The lower source/drain regions 140 and the upper source/drain regions 150 may each include a semiconductor layer (e.g., a silicon (Si) layer, a silicon carbide (SiC) layer, and/or a silicon germanium (SiGe) layer) and may additionally include dopants in the semiconductor layer. For example, each of the source/drain regions 140, 150 may include an epitaxial semiconductor layer having dopants (i.e., impurities) therein. In some embodiments, the upper source/drain regions 150 may include a different semiconductor material from that of the lower source/drain regions 140. As an example, the upper source/drain regions 150 may include silicon germanium, and the lower source/drain regions 140 may include silicon or silicon carbide, or vice versa. In some other embodiments, the upper source/drain regions 150 may include the same semiconductor material as the lower source/drain regions 140. The lower source/drain regions 140 may be on the substrate 110, and the upper source/drain regions 150 may be on the lower source/drain regions 140.

In some embodiments, the lower source/drain regions 140 have a first conductivity type and the upper source/drain regions 150 have a second conductivity type. As used herein, the terms “first conductivity type” and “second conductivity type” are used to indicate either n-type or p-type, where the first and second conductivity types are different from each other. Thus, if a first region of a device has a first conductivity type and a second region of the device has a second conductivity type, this means either that the first region has n-type conductivity and the second region has p-type conductivity or, alternatively, that the first region has p-type conductivity and the second region has n-type conductivity. For example, the lower source/drain regions 140 may include n-type impurities (e.g., phosphorus (P), arsenic (As), antimony (Sb), etc.) and the upper source/drain regions 150 may include p-type impurities (e.g., boron (B), gallium (Ga), indium (In), etc.), or vice versa.

The upper and lower transistors Ta, Tb may be stacked in the third direction Z on the substrate 110. In some embodiments, the lower transistor Tb and the upper transistor Ta may have complementary conductivity types to form a complementary metal-oxide-semiconductor (CMOS) structure. For example, the lower transistor Tb may have a first conductivity type, while the upper transistor Ta may have a second conductivity type. In some embodiments, the upper and lower transistors Ta, Tb may be PMOS and NMOS transistors, respectively, or vice versa. Also, while illustrated with reference to the lower transistor Tb and the upper transistor Ta, it will be understood that the transistor stack 101 is not limited to a two-transistor arrangement, and may include additional transistors that are vertically stacked on the substrate 110, in some other embodiments. For simplicity of illustration, only one transistor stack 101 is shown in FIG. 1A. It will be understood, however, that the integrated circuit device 100 may include two, three, four, or more transistor stacks 101 in some embodiments.

FIG. 1B is a schematic plan view (or layout view) illustrating an integrated circuit device according to some embodiments. For simplicity of illustration, FIG. 1B only shows some elements of the integrated circuit device 100. A line A-A’ is taken along a gate cut region 132, a lower source/drain region 140, and an upper source/drain region 150 in the first direction Y. A line B-B’ is taken along the gate cut region 132 and a first gate structure 170-1 in the first direction Y. FIG. 1C is a schematic cross-sectional view taken along line A-A’ of FIG. 1B. FIG. 1D is a schematic cross-sectional view taken along line B-B’ of FIG. 1B.

Referring to FIGS. 1B, 1C, and 1D, the integrated circuit device 100 includes a plurality of first gate structures 170-1 and a plurality of second gate structures 170-2 that extend (i.e., longitudinally extend) in the first direction Y. A respective first gate structure 170-1 is on the upper channel layers 120a of the upper transistor Ta and the lower channel layers 120b of the lower transistor Tb. In some embodiments, each gate structure 170 may include an upper gate structure 170a and a lower gate structure 170b. As used herein, like elements may be referred to individually by their full reference numeral (e.g., the first gate structure 170-1) and may be referred to collectively by the first part of their reference numeral (e.g., the gate structures 170).

The upper transistor Ta includes the upper channel layers 120a, a respective upper gate structure 170a on the upper channel layers 120a, and the pair of upper source/drain regions 150 on opposite sides of the respective upper gate structure 170a in the second direction X. The lower transistor Tb includes the lower channel layers 120b, a respective lower gate structure 170b on the lower channel layers 120b, and the pair of lower source/drain regions 140 on opposite sides of the respective lower gate structure 170b in the second direction X. The lower transistor Tb and the upper transistor Ta comprise the transistor stack 101 (see FIG. 1A) of the integrated circuit device 100.

The pair of upper source/drain regions 150 may be spaced apart from each other (e.g., in the second direction X), with the upper gate structure 170a therebetween. The pair of lower source/drain regions 140 may be spaced apart from each other (e.g., in the second direction X), with the lower gate structure 170b therebetween. In some embodiments, lengths of the lower source/drain regions 140 in the first direction Y may be greater than lengths of the upper source/drain regions 150 in the first direction Y, and thus portions of the lower source/drain regions 140 may be free of overlap in the third direction Z with the upper source/drain regions 150, as shown in FIGS. 1B and 1C.

The upper channel layers 120a may be between (e.g., in the second direction X) the pair of upper source/drain regions 150 and are electrically connected to the pair of upper source/drain regions 150. As shown in FIG. 1D, the upper channel layers 120a may be spaced apart from each other in the third direction Z, with the upper gate structure 170a therebetween. Although FIG. 1D illustrates three upper channel layers 120a, embodiments of the present disclosure are not limited thereto. In some embodiments, the integrated circuit device 100 may include more than three upper channel layers 120a or less than three upper channel layers 120a.

The lower channel layers 120b may be between (e.g., in the second direction X) the pair of lower source/drain regions 140 and are electrically connected to the pair of lower source/drain regions 140. As shown in FIG. 1D, the lower channel layers 120b may be spaced apart from each other in the third direction Z, with the lower gate structure 170b therebetween. Although FIG. 1D illustrates two lower channel layers 120b, embodiments of the present disclosure are not limited thereto. In some embodiments, the integrated circuit device 100 may include more than two lower channel layers 120b.

The upper gate structure 170a may be on the upper channel layers 120a of the upper transistor Ta, and the lower gate structure 170b may be on the lower channel layers 120b of the lower transistor Tb. The upper gate structure 170a includes a gate insulator 172 and an upper conductive gate 174a. The upper conductive gate 174a may be between, in the third direction Z, the upper channel layers 120a. The upper conductive gate 174a may be spaced apart from the upper source/drain regions 150 in the second direction X, with the gate insulator 172 therebetween. The lower gate structure 170b includes the gate insulator 172 and a lower conductive gate 174b. The lower conductive gate 174b may be between, in the third direction Z, the lower channel layers 120b. The lower conductive gate 174b may be spaced apart from the lower source/drain regions 140 in the second direction X, with the gate insulator 172 therebetween.

The upper gate structure 170a may surround the upper channel layers 120a. That is, the upper gate structure 170a (e.g., the upper conductive gate 174a) may be on an upper surface, a lower surface, and a side surface of each upper channel layer 120a. The gate insulator 172 may be between each upper channel layer 120a and the upper conductive gate 174a, and may separate the upper conductive gate 174a from the upper channel layers 120a. It will be understood that “an element A surrounds an element B” (or similar language) as used herein means that the element A is at least partially around the element B but does not necessarily mean that the element A completely encloses the element B.

The lower gate structure 170b may surround the lower channel layers 120b. That is, the lower gate structure 170b (e.g., the lower conductive gate 174b) may be on an upper surface, a lower surface, and a side surface of each lower channel layer 120b. The gate insulator 172 may be between each lower channel layer 120b and the lower conductive gate 174b, and may separate the lower conductive gate 174b from the lower channel layers 120b.

The upper conductive gate 174a and the lower conductive gate 174b may each include a metal material (e.g., tungsten (W), aluminum (Al), copper (Cu), molybdenum (Mo), cobalt (Co), and/or ruthenium (Ru)) and/or a semiconductor material. In some embodiments, the upper conductive gate 174a and the lower conductive gate 174b may each include a metal layer and work function layer(s) (e.g., a TiN layer, a TaN layer, a TiAl layer, a TiC layer, a TiAlC layer, a TiAlN layer and/or a WN layer). For example, the work function layer(s) may be provided between the metal layer and the gate insulator 172. In some embodiments, the work function layer(s) may separate the metal layer from the gate insulator 172. In some embodiments, the upper conductive gate 174a and the lower conductive gate 174b may include the same metal material. In some other embodiments, the upper conductive gate 174a and the lower conductive gate 174b may include different metal materials. In some embodiments, the upper and lower conductive gates 174a, 174b may comprise an integrated unitary structure (e.g., formed by the same process or the same series of processes), although the present disclosure is not limited thereto.

As shown in FIG. 1D, the upper gate structure 170a (e.g., the upper conductive gate 174a) and the lower gate structure 170b (e.g., the lower conductive gate 174b) may be in electrical contact with each other (i.e., may be electrically connected to each other) and may share an interface 174_I (shown by a dashed line in FIG. 1D). In some embodiments, a common gate signal may be applied to both the upper conductive gate 174a and the lower conductive gate 174b (e.g., through an upper gate contact 178). In some other embodiments, different from that shown, the isolation region 130 may separate (e.g., electrically isolate) the upper conductive gate 174a from the lower conductive gate 174b, such that the upper and lower conductive gates 174a, 174b may be configured to receive separate gate signals.

The gate insulator 172 extends between the upper channel layers 120a and the upper conductive gate 174a, and between the lower channel layers 120b and the lower conductive gate 174b. The gate insulator 172 may surround the upper and lower conductive gates 174a, 174b and may separate (i.e., insulate) the upper and lower conductive gates 174a, 174b from the upper and lower channel layers 120a, 120b, respectively. In some embodiments, the gate insulator 172 may also extend on the substrate 110 (i.e., on the first surface S1 of the substrate 110) and on a shallow trench isolation (STI) region 116 (described in greater detail below), as shown in FIG. 1D. The gate insulator 172 may include a single layer or multiple layers (e.g., a silicon oxide layer and/or a high-k material layer). For example, the high-k material layer may include Al₂O₃, HfO₂, ZrO₂, HfZrO₄, TiO₂, Sc₂O₃, Y₂O₃, La₂O₃, Lu₂O₃, Nb₂O₅ and/or Ta₂O₅.

As shown in FIG. 1B, the gate structures 170 may extend lengthwise (i.e., longitudinally) in the first direction Y and may be spaced apart in the second direction X. The first gate structures 170-1 may be adjacent to the second gate structures 170-2 in the first direction Y. The gate cut region 132 (described in greater detail below) may separate adjacent first and second gate structures 170-1, 170-2 in the first direction Y. In some embodiments, the outermost pair of first gate structures 170-1 in the second direction X may be dummy gate structures that do not function electrically (e.g., non-active gate structures) and may be formed to replicate a physical structure of the active first gate structure 170-1 therebetween, although the present disclosure is not limited thereto. Similarly, in some embodiments, the outermost pair of second gate structures 170-2 in the second direction X may be dummy gate structures that do not function electrically (e.g., non-active gate structures) and may be formed to replicate a physical structure of the active second gate structure 170-2 therebetween, although the present disclosure is not limited thereto.

The isolation region 130 may be a spacer that separates (i.e., electrically isolates) the lower channel layers 120b of the lower transistor Tb from the upper channel layers 120a of the upper transistor Ta. The isolation region 130 may be between the upper gate structure 170a and the lower gate structure 170b (e.g., in the third direction Z). In some embodiments, the isolation region 130 may also be between the lower and upper source/drain regions 140, 150 (e.g., in the third direction Z), as shown in FIG. 1C. The isolation region 130 may include, for example, one or more isolation layers including insulating material(s) (e.g., silicon oxide, silicon oxynitride, silicon nitride, silicon carbonitride, silicon boron carbonitride, and/or a low-k material).

In some embodiments, the lower channel layers 120b may be wider, in the first direction Y, than the upper channel layers 120a. For example, in some embodiments, the lower channel layers 120b may be at least twice as wide as the upper channel layers 120a in the first direction Y. In some embodiments, the isolation region 130 may have the same width as the lower channel layers 120b in the first direction Y. In some other embodiments, different from that shown, the isolation region 130 may have the same width as the upper channel layers 120a in the first direction Y.

STI regions 116 may be formed adjacent to the substrate 110 on opposite sides of the upper and lower transistors Ta, Tb (e.g., in the first direction Y). The STI regions 116 may include, for example, one or more layers including insulating material(s) (e.g., silicon oxide, silicon oxynitride, silicon nitride, silicon carbonitride, silicon boron carbonitride, and/or a low-k material). For example, the STI regions 116 may define active regions of the integrated circuit device 100 and may isolate (e.g., electrically isolate) adjacent transistor stacks 101 (see FIG. 1A). Although FIGS. 1C and 1D illustrate that the STI regions 116 include a single layer, in some embodiments, the STI regions 116 may include multiple layers.

The integrated circuit device 100 further includes an interlayer insulating layer 152 on (i.e., surrounding) the lower and upper source/drain regions 140, 150. For example, the interlayer insulating layer 152 may be between, in the third direction Z, the substrate 110 and an upper structure 138 (described in greater detail below). The interlayer insulating layer 152 may include, for example, insulating material(s) (e.g., silicon oxide, silicon oxynitride, silicon nitride, silicon carbonitride, silicon boron carbonitride, and/or a low-k material). Although FIGS. 1C and 1D illustrate the interlayer insulating layer 152 as a single layer, in some embodiments, the interlayer insulating layer 152 may include multiple layers.

In some embodiments, an upper gate contact 178 extends into the interlayer insulating layer 152 and may electrically connect the lower gate structure 170b (e.g., the lower conductive gate 174b) and the upper gate structure 170a (e.g., the upper conductive gate 174a) to the upper structure 138. The upper gate contact 178 may include a metal layer or material including, for example, W, Al, Cu, Mo, Co and/or Ru. In some other embodiments, different from that shown, the upper gate contact 178 may be formed beneath (i.e., on a backside) of the upper and lower gate structures 170a, 170b.

The integrated circuit device 100 further includes the upper structure 138 (which may also be referred to as a BEOL structure) on the upper and lower transistors Ta, Tb. The upper structure 138 may include elements formed during the middle-of-line (MOL) portion and/or the back-end-of-line (BEOL) portion of device fabrication. For ease of illustration, the elements of the upper structure 138 are not specifically shown in FIGS. 1C and 1D. As shown in FIGS. 1C and 1D, the upper structure 138 is provided on the first surface S1 (i.e., the frontside) of the substrate 110.

The upper structure 138 may include conductive elements (e.g., wire(s) and/or via(s)) and insulating elements (e.g., interlayer insulating layer(s) and/or spacer(s)). For example, the upper structure 138 may include interlayer insulating layers, conductive wires (e.g., metal wires) that are provided in the interlayer insulating layers and are stacked in the third direction Z, and conductive via plugs (e.g., metal via plugs), each of which may electrically connect two conductive wires that are spaced apart from each other in the third direction Z. The conductive elements of the upper structure 138 may be electrically connected to, for example, the lower source/drain regions 140, the upper source/drain regions 150, and/or the gate structures 170.

The upper transistor Ta (including the upper channel layers 120a, the pair of upper source/drain regions 150, and the upper gate structure 170a) and the lower transistor Tb (including the lower channel layers 120b, the pair of lower source/drain regions 140, and the lower gate structure 170b) are provided on the first surface S1 (i.e., the frontside) of the substrate 110. The integrated circuit device 100 further includes a backside power delivery network (BSPDN) structure 142 on the second surface S2 (i.e., the backside) of the substrate 110. The BSPDN structure 142 may include a backside insulator 146 and a plurality of backside power rails 144 provided in the backside insulator 146. The backside power rails 144 may include a metal layer or material including, for example, tungsten (W), aluminum (Al), copper (Cu), molybdenum (Mo), cobalt (Co) and/or ruthenium (Ru). The backside insulator 146 may include, for example, one or more layers including insulating material(s) (e.g., silicon oxide, silicon oxynitride, silicon nitride, silicon carbonitride, silicon boron carbonitride, and/or a low-k material).

The backside power rails 144 may extend (i.e., may longitudinally extend) in the second direction X. Each backside power rail 144 may be electrically connected to a power source with a predetermined voltage (e.g., a drain voltage (VDD) and/or a source voltage (VSS)). In some embodiments, at least one lower source/drain region 140 of the lower transistor Tb may be electrically connected to the power source through a backside contact structure 148 (described in greater detail below) and a backside power rail 144, as shown in FIG. 1C. That is, the lower source/drain region 140 may receive a drain voltage (VDD) or a source voltage (VSS) via the backside contact structure 148 and the backside power rail 144. Further, at least one upper source/drain region 150 of the upper transistor Ta may be electrically connected to the power source through an upper source/drain contact 156, a contact power rail structure 122 (described in greater detail below), and a backside power rail 144, as shown in FIG. 1C. That is, the upper source/drain region 150 may receive a drain voltage (VDD) or a source voltage (VSS) via the upper source/drain contact 156, the contact power rail structure 122, and the backside power rail 144. As used herein, the backside power rail 144 that is electrically connected to the contact power rail structure 122 may also be referred to as a “first backside power rail,” and the backside power rail 144 that is electrically connected to the backside contact structure 148 may also be referred to as a “second backside power rail.” For example, the BSPDN structure 142 may include a power delivery network having a wiring network, which is used to deliver power (e.g., source/drain voltages) to the backside power rails 144.

For ease of illustration, the BSPDN structure 142 is shown in FIGS. 1C and 1D as including only the backside power rails 144 and the backside insulator 146. It will be understood, however, that embodiments of the present disclosure are not limited thereto, and the BSPDN structure 142 may (and typically does) include various other elements (e.g., power wire(s), via(s), interlayer insulating layer(s), and the like). For example, the BSPDN structure 142 may include conductive via plug(s) and/or conductive wire(s) that electrically connect to one or more of the backside power rails 144 to facilitate power delivery. That is, while illustrated as including the backside power rails 144 and the backside insulator 146, it will be understood that the BSPDN structure 142 may include one or more conductive layers (e.g., metal layers) stacked in the third direction Z that provide backside power delivery. The conductive layers may be included in interlayer insulating layers, and conductive via plugs (e.g., metal via plugs) may electrically connect the conductive layers to each other in the third direction Z. For example, although the backside insulator 146 is illustrated as a single layer, in some embodiments, the backside insulator 146 may include multiple interlayer insulating layers stacked on the second surface S2 of the substrate 110 (e.g., in the third direction Z). The conductive layers may include one or more conductive wires (e.g., metal wires). In some embodiments, an intervening structure (not shown) may be provided between the substrate 110 and the BSPDN structure 142 and may separate the substrate 110 from the BSPDN structure 142. The BSPDN structure 142 may increase the efficiency of power delivery, reduce an area used for power delivery, and/or improve a voltage drop in the integrated circuit device 100.

The backside contact structure 148 may be configured to deliver a drain voltage (VDD) or a source voltage (VSS) from the BSPDN structure 142 (i.e., from a backside power rail 144) to the lower source/drain region 140 of the lower transistor Tb. The backside contact structure 148 may be between the backside power rail 144 and the lower source/drain region 140 (e.g., in the third direction Z). For example, the backside contact structure 148 may extend into the substrate 110 and may electrically connect the BSPDN structure 142 (i.e., the backside power rail 144) to the lower source/drain region 140. In some embodiments, one or more conductive plugs (not specifically shown) may be provided between the backside contact structure 148 and the backside power rail 144, although the present disclosure is not limited thereto. For example, the backside contact structure 148 and the conductive plug(s) may include the same materials and may be integrated in a monolithic or unitary structure, that is, a structure formed by the same process or the same series of processes without a structurally or visibly separate interface therebetween. The backside contact structure 148 may include a metal layer or material including, for example, tungsten (W), aluminum (Al), copper (Cu), molybdenum (Mo), cobalt (Co) and/or ruthenium (Ru). Although not specifically shown, backside contact structures 148 may be used to electrically connect both lower source/drain regions 140 of the lower transistor Tb to the BSPDN structure 142 in some embodiments, but the present disclosure is not limited thereto.

The integrated circuit device 100 further includes the upper source/drain contact 156 (shown by a dashed box in FIG. 1B) and the contact power rail structure 122. The upper source/drain contact 156 may be on the upper source/drain region 150 of the upper transistor Ta and may be in contact with (e.g., may be in electrical contact with) the upper source/drain region 150. For example, the upper source/drain contact 156 may be in contact with (e.g., may be directly on) an upper surface of the upper source/drain region 150. The upper source/drain contact 156 is electrically connected to (i.e., is electrically connected between) the upper source/drain region 150 and the contact power rail structure 122. For example, the upper source/drain contact 156 may extend in the first direction Y to electrically connect the upper source/drain region 150 to the contact power rail structure 122, as shown in FIGS. 1B and 1C. The upper source/drain contact 156 may include a metal layer or material including, for example, tungsten (W), aluminum (Al), copper (Cu), molybdenum (Mo), cobalt (Co) and/or ruthenium (Ru).

The contact power rail structure 122 may be configured to deliver a drain voltage (VDD) or a source voltage (VSS) from the BSPDN structure 142 (i.e., from a backside power rail 144) to the upper source/drain region 150 of the upper transistor Ta. That is, the contact power rail structure 122 may electrically connect the BSPDN structure 142 (i.e., the backside power rail 144) to the upper source/drain region 150. For example, the contact power rail structure 122 may be a vertical conductive structure that electrically connects the backside power rail 144 to the upper source/drain region 150. As used herein, “an element X electrically connects an element Y to an element Z” (or similar language) means that the element X facilitates an electrical connection between the element Y and the element Z but does not necessarily mean that the element X is the only element that facilitates the electrical connection (i.e., other intervening elements may also be present that facilitate the electrical connection). For example, the contact power rail structure 122 may be electrically connected to the upper source/drain region 150 through the upper source/drain contact 156. Although not specifically shown, the contact power rail structure 122 may be used to electrically connect both upper source/drain regions 150 of the upper transistor Ta to the BSPDN structure 142 in some embodiments, and/or to electrically connect upper source/drain region(s) of other upper transistors to the BSPDN structure 142 in some embodiments, but the present disclosure is not limited thereto.

The contact power rail structure 122 may extend into the STI region 116 to electrically connect to the backside power rail 144. In some embodiments, the contact power rail structure 122 may be surrounded by the STI region 116 and the interlayer insulating layer 152. The contact power rail structure 122 may include a metal layer or material including, for example, tungsten (W), aluminum (Al), copper (Cu), molybdenum (Mo), cobalt (Co) and/or ruthenium (Ru). Although FIGS. 1B, 1C, and 1D illustrate that the contact power rail structure 122 includes a single conductive layer, in some embodiments, the contact power rail structure 122 may include multiple conductive layers.

In some embodiments, the contact power rail structure 122 may be formed in a gate cut region 132, as shown in FIG. 1B. For example, the contact power rail structure 122 may extend in the gate cut region 132 in the second direction X. The gate cut region 132 may separate (e.g., may electrically isolate) adjacent first and second gate structures 170-1, 170-2 in the first direction Y. In other words, upper and lower gate structures 170a, 170b of a first gate structure 170-1 may be separated from adjacent upper and lower gate structures 170a, 170b of a second gate structure 170-2 in the first direction Y by the gate cut region 132. For example, the first gate structure 170-1 may be adjacent to and spaced apart from the second gate structure 170-2 in the first direction Y, with the contact power rail structure 122 therebetween. The gate cut region 132 may extend in the second direction X to separate and electrically isolate the first gate structure 170-1 and the second gate structure 170-2 in the first direction Y.

The gate cut region 132 includes a contact insulating layer 124 (which may also be referred to as a gate cut insulating layer) and a contact insulating liner 126 (which may also be referred to as a gate cut insulating liner). In some embodiments, the contact power rail structure 122 may extend into the contact insulating layer 124 and the contact insulating liner 126. For example, the contact insulating layer 124 and the contact insulating liner 126 may help electrically isolate the contact power rail structure 122 from the gate structures 170 to avoid an unintended electrical connection (i.e., an electrical short) therebetween.

The contact insulating layer 124 and the contact insulating liner 126 may be between the contact power rail structure 122 and the gate structures 170 in the first direction Y. For example, the contact insulating layer 124 may be between the contact insulating liner 126 and the contact power rail structure 122 in the first direction Y. The contact insulating layer 124 may be on opposing side surfaces of the contact power rail structure 122 in the first direction Y. For example, the contact insulating layer 124 may extend in the second direction X on the opposing side surfaces of the contact power rail structure 122. The contact insulating liner 126 may also be on the opposing side surfaces of the contact power rail structure 122 in the first direction Y. For example, the contact insulating liner 126 may extend in the second direction X on the opposing side surfaces of the contact power rail structure 122. In some embodiments, the contact insulating layer 124 may be in contact with (e.g., may be directly on) the opposing side surfaces of the contact power rail structure 122 in the first direction Y, and the contact insulating liner 126 may be in contact with (e.g., may be directly on) the contact insulating layer 124.

In some embodiments, the contact insulating layer 124 and the contact insulating liner 126 may extend into the STI region 116. For example, the contact insulating layer 124 and the contact insulating liner 126 may be surrounded by the STI region 116 and the interlayer insulating layer 152. The contact insulating layer 124 and the contact insulating liner 126 may include, for example, insulating material(s) (e.g., silicon oxide, silicon oxynitride, silicon nitride, silicon carbonitride, silicon boron carbonitride, and/or a low-k material). In some embodiments, the contact insulating layer 124 may include a first insulating material, and the contact insulating liner 126 may include a second insulating material different from the first insulating material. For example, the contact insulating layer 124 may include an oxide material, and the contact insulating liner 126 may include a nitride material, although embodiments are not limited thereto.

As shown in FIG. 1B, the contact power rail structure 122 may have a line (or rail) shape in a plan view. That is, the contact power rail structure 122 may have an elongated shape that extends in the second direction X. As such, the contact power rail structure 122 may overlap two or more of the gate structures 170 in the first direction Y. In other words, the contact power rail structure 122 may extend between the first and second gate structures 170-1, 170-2 that are on opposite sides of the gate cut region 132. The contact power rail structure 122 may overlap the lower gate structure 170b of the lower transistor Tb and the upper gate structure 170a of the upper transistor Ta in the first direction Y, as shown in FIG. 1D. Further, the contact power rail structure 122 may overlap the lower channel layers 120b of the lower transistor Tb and the upper channel layers 120a of the upper transistor Ta in the first direction Y. The contact power rail structure 122 may also overlap the pair of lower source/drain regions 140 of the lower transistor Tb and the pair of upper source/drain regions 150 of the upper transistor Ta in the first direction Y, as shown in FIGS. 1B and 1C.

A width W_{CPR} of the contact power rail structure 122 in the second direction X may be greater than a width W_{S/D} of each lower source/drain region 140 and each upper source/drain region 150 in the second direction X, as shown in FIG. 1B. For example, the width W_{CPR} of the contact power rail structure 122 may be at least two times greater than the width W_{S/D} of each lower source/drain region 140 and each upper source/drain region 150. In some embodiments, the width W_{CPR} of the contact power rail structure 122 may be substantially equal to a width of the contact insulating layer 124 and a width of the contact insulating liner 126 in the second direction X.

The line (or rail) shape of the contact power rail structure 122 may increase the width and cross-sectional area of the contact power rail structure 122, as well as its contact area with the backside power rail 144 and the upper source/drain contact 156. As such, the configuration of the contact power rail structure 122 may advantageously reduce contact resistance with the backside power rail 144 and the upper source/drain contact 156, mitigate current crowding by distributing current more uniformly across a larger area, and reduce a voltage drop during backside power delivery to the upper source/drain region 150 of the upper transistor Ta. Accordingly, the performance and reliability of the integrated circuit device 100 may be improved.

In some embodiments, the integrated circuit device 100 may further include a polycrystalline silicon (polysilicon) layer 128 and a blocking layer 134 between, in the first direction Y, the contact power rail structure 122 and the upper and lower conductive gates 174a, 174b of the upper and lower transistors Ta, Tb, as shown in FIG. 1D. The polysilicon layer 128 and the blocking layer 134 may also be between, in the first direction Y, the contact power rail structure 122 and the upper and lower channel layers 120a, 120b of the upper and lower transistors Ta, Tb. For example, the polysilicon layer 128 and the blocking layer 134 may help electrically isolate the contact power rail structure 122 from the upper and lower channel layers 120a, 120b and from the gate structures 170 to avoid an unintended electrical connection (i.e., an electrical short) therebetween.

The polysilicon layer 128 may be between the contact power rail structure 122 and the blocking layer 134 in the first direction Y. The blocking layer 134 may be between the upper and lower channel layers 120a, 120b and the polysilicon layer 128 in the first direction Y. For example, the polysilicon layer 128 and the blocking layer 134 may extend on side surfaces of the upper and lower channel layers 120a120b. In some embodiments, the contact insulating layer 124, the contact insulating liner 126, the polysilicon layer 128, and the blocking layer 134 may be sequentially stacked on a side surface of the contact power rail structure 122 in the first direction Y. For example, the polysilicon layer 128 may be in contact with (e.g., may be directly on) the contact insulating liner 126.

In some embodiments, the polysilicon layer 128 may be a portion of polysilicon that remains (i.e., unstripped polysilicon) during a replacement metal gate (RMG) process to form the gate structures 170 (described in greater detail below). The upper and lower channel layers 120a, 120b may include a semiconductor material (e.g., single-crystal silicon (Si), Ge, SiGe, GaP, GaAs, SiC, SiGeC and/or InP) that is different from the polysilicon layer 128. The blocking layer 134 may include insulating material(s) (e.g., silicon oxide, silicon oxynitride, silicon nitride, silicon carbonitride, silicon boron carbonitride, and/or a low-k material). In some embodiments, the blocking layer 134 may include an oxide material (e.g., silicon oxide).

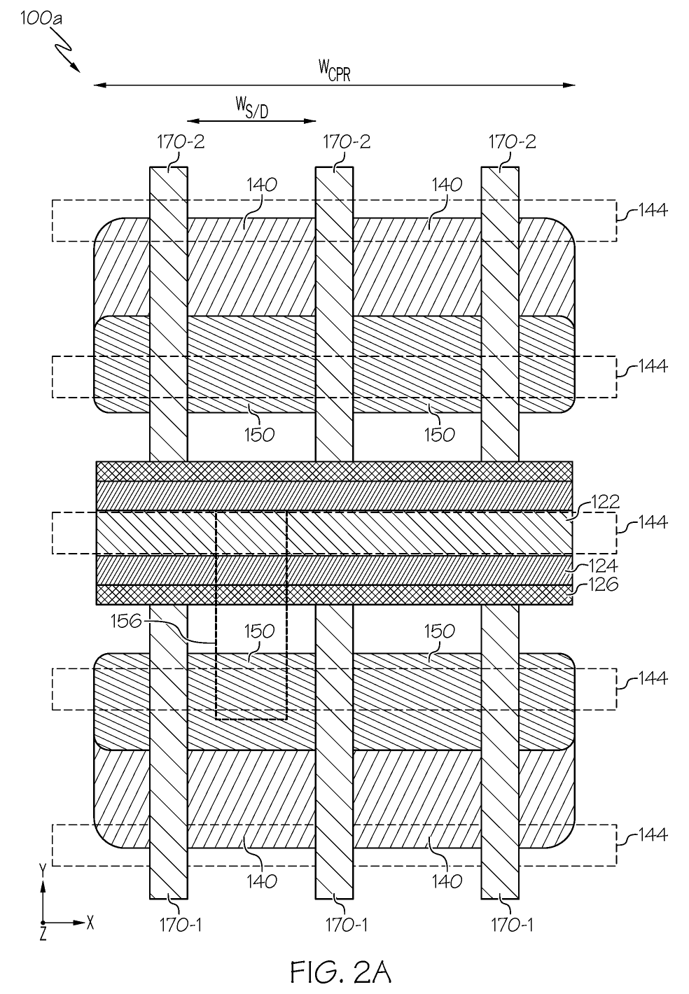

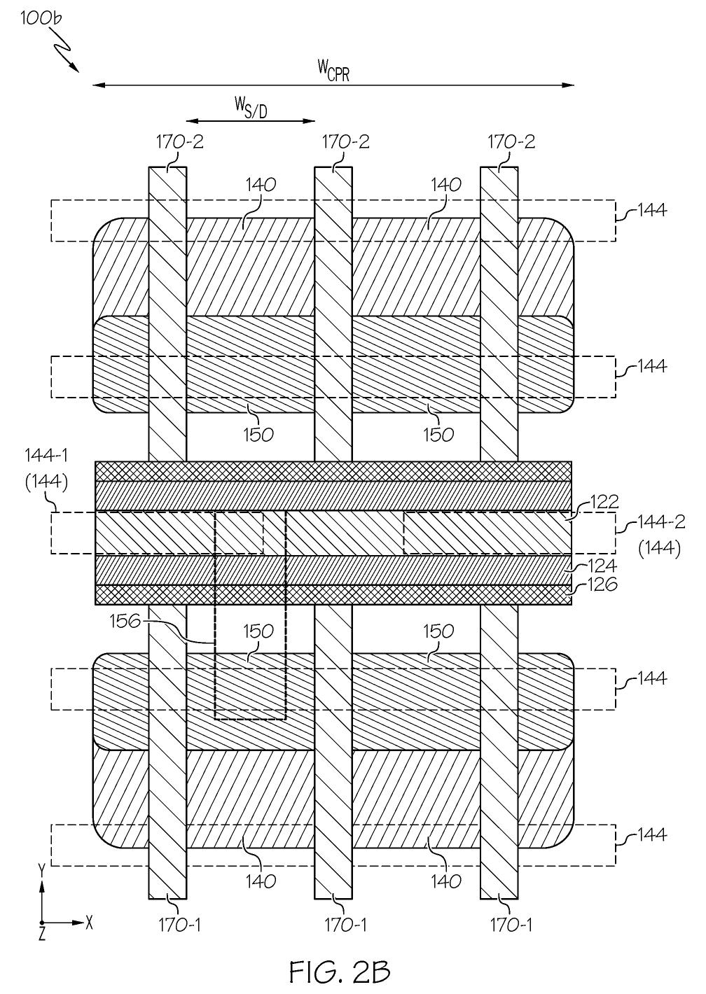

FIGS. 2A and 2B are schematic plan views (or layout views) illustrating backside power rails of integrated circuit devices according to some embodiments. Repeated description of like elements described above may be omitted for ease of description.

Referring to FIG. 2A, an integrated circuit device 100a may include backside power rails 144 (shown by dashed lines) that extend (i.e., longitudinally extend) in the second direction X. As shown in FIG. 2A, a respective backside power rail 144 that is electrically connected to the contact power rail structure 122 may extend continuously in the second direction X on a lower surface of the contact power rail structure 122, according to some embodiments.

Referring to FIG. 2B, an integrated circuit device 100b may include backside power rails 144 (shown by dashed lines) that extend (i.e., longitudinally extend) in the second direction X. As shown in FIG. 2B, a respective backside power rail 144 that is electrically connected to the contact power rail structure 122 may extend discontinuously in the second direction X on a lower surface of the contact power rail structure 122, according to some embodiments. That is, the respective backside power rail 144 may include a first portion 144-1 (which may also be referred to as a first segment) and a second portion 144-2 (which may also be referred to as a second segment) that are both electrically connected to the contact power rail structure 122 and are spaced apart from each other in the second direction X, as shown in FIG. 2B. Still referring to FIG. 2B and referring back to FIG. 1D, while a backside power rail 144 is shown beneath (and electrically connected to) the contact power rail structure 122 in FIG. 1D, it will be understood that this backside power rail 144 may not be visible in the cross-sectional view of FIG. 1D when it has the configuration shown in the plan view of FIG. 2B.

Referring to FIGS. 2A and 2B, the line (or rail) shape of the contact power rail structure 122 may allow the backside power rail 144 to include multiple discontinuous portions (e.g., portions 144-1, 144-2), each of which remains electrically connected to the contact power rail structure 122 due to its elongated shape (see FIG. 2B), or alternatively, may allow the backside power rail 144 to extend continuously beneath the contact power rail structure 122 (see FIG. 2A). Accordingly, the configuration of the contact power rail structure 122 may provide design flexibility for the backside power rail 144, enabling optimized power delivery for the BSPDN structure 142 and/or enhanced layout efficiency for the integrated circuit device.

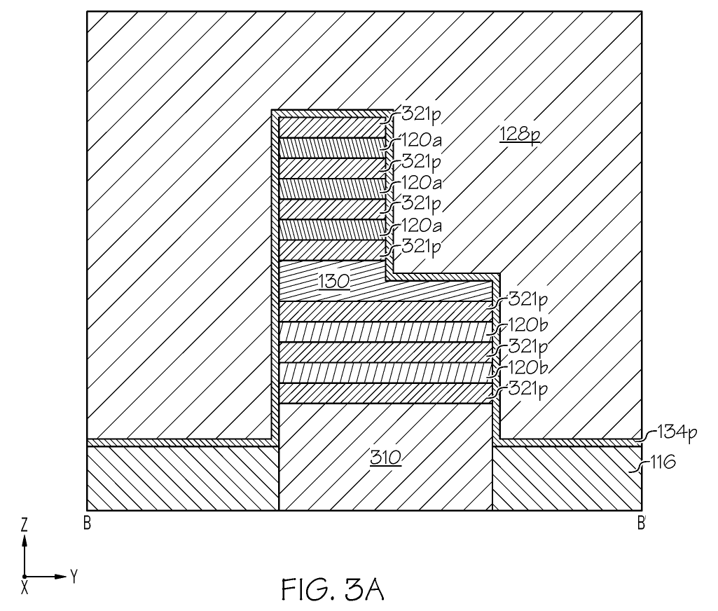

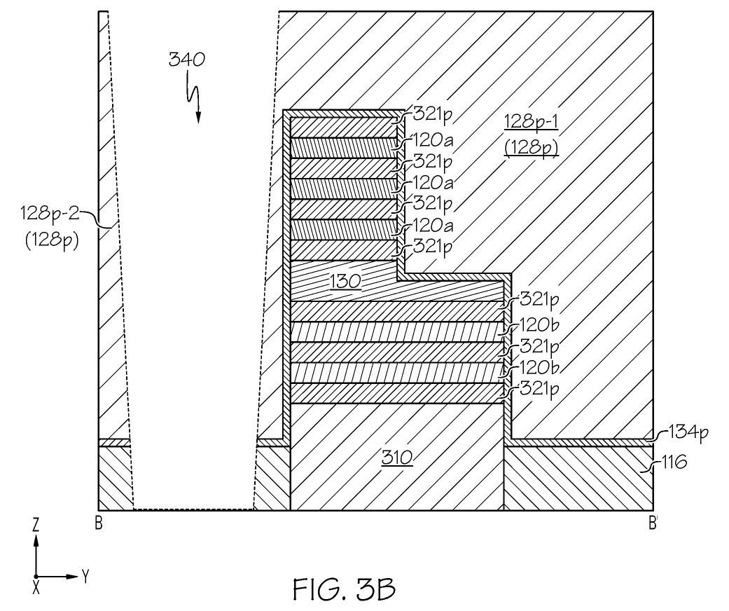

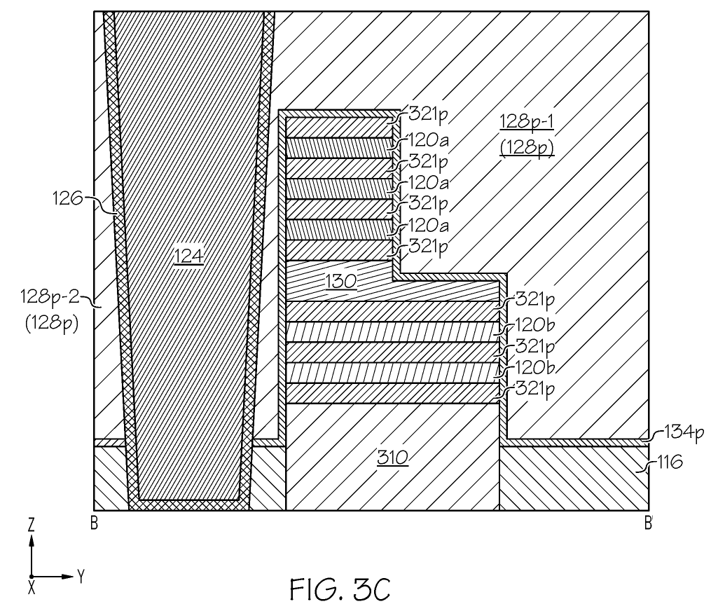

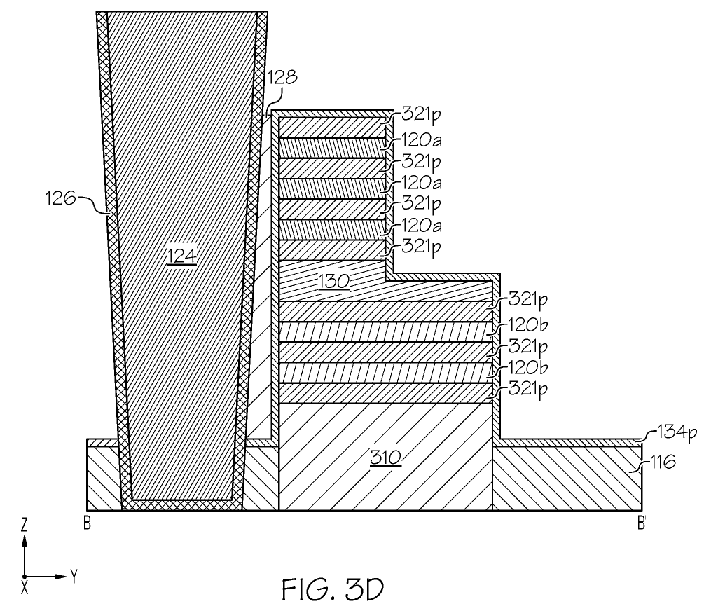

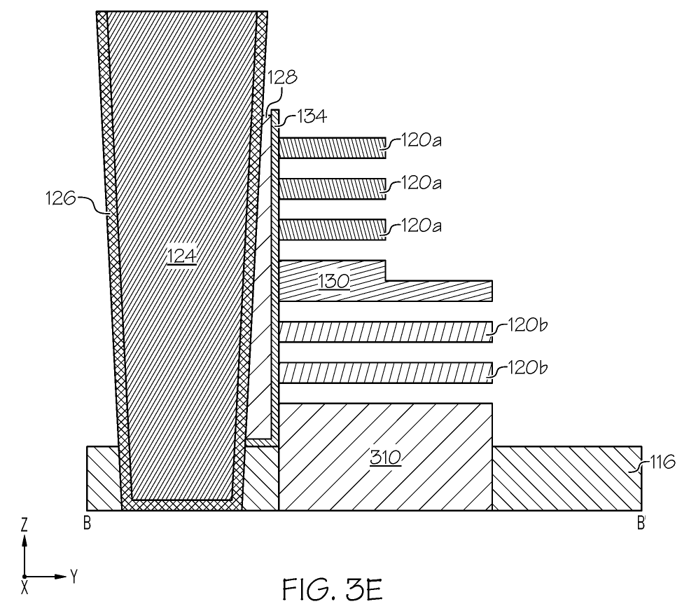

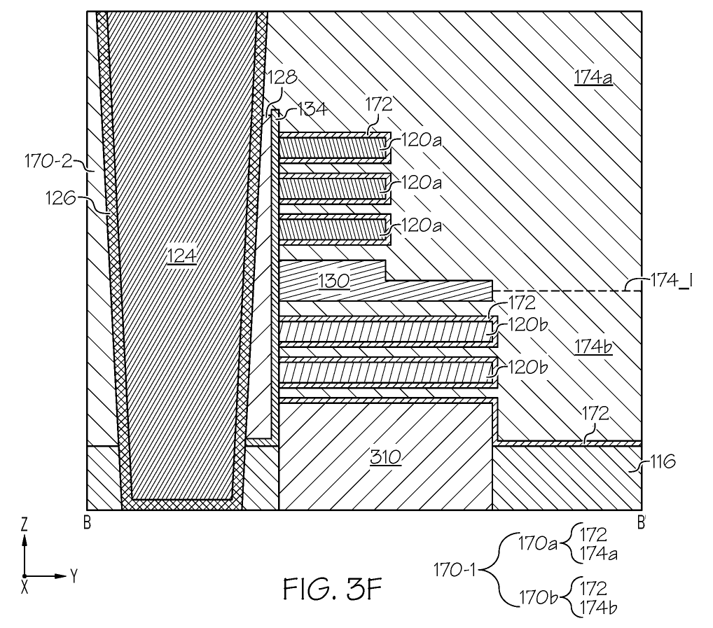

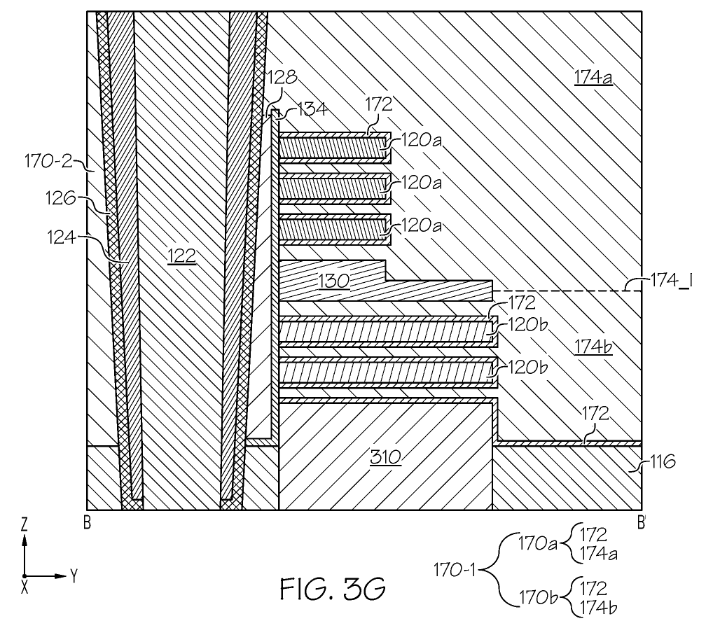

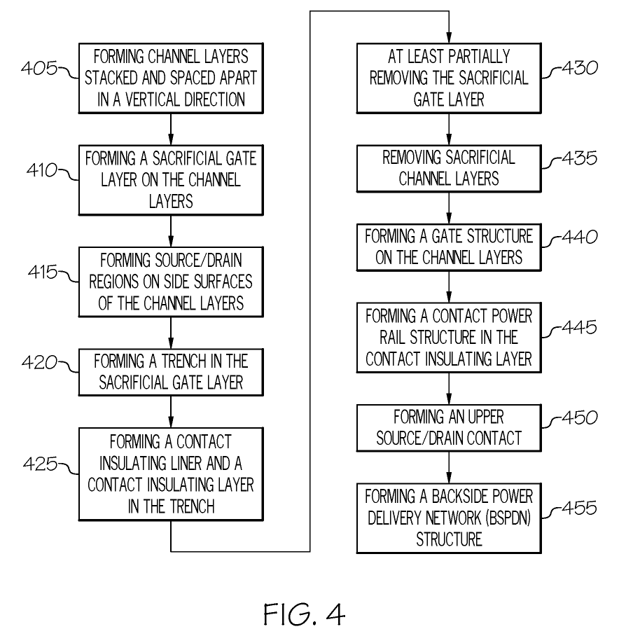

FIGS. 3A, 3B, 3C, 3D, 3E, 3F, and 3G are schematic cross-sectional views illustrating a method of forming an integrated circuit device according to some embodiments. In particular, FIGS. 3A, 3B, 3C, 3D, 3E, 3F, and 3G are schematic cross-sectional views corresponding to the line B-B’ of FIG. 1B. FIG. 4 is a flowchart illustrating a method of forming an integrated circuit device according to some embodiments. Repeated description of like elements described above may be omitted for ease of description.

Referring to FIGS. 3A and 4, upper and lower channel layers 120a, 120b stacked and spaced apart in the third direction Z (i.e., a vertical direction) may be formed (Block 405 in FIG. 4). In some embodiments, the upper and lower channel layers 120a, 120b may be alternately stacked with sacrificial channel layers 321p in the third direction Z. For example, the lower channel layers 120b may be alternately stacked with lower ones of the sacrificial channel layers 321p in the third direction Z, and the upper channel layers 120a may be alternately stacked with upper ones of the sacrificial channel layers 321p in the third direction Z. The upper channel layers 120a may be on the lower channel layers 120b in the third direction Z.

The upper and lower channel layers 120a, 120b may be semiconductor layers. In some embodiments, the upper and lower channel layers 120a, 120b may include, for example, silicon (e.g., may be silicon layers). The sacrificial channel layers 321p may have an etch selectivity (i.e., may exhibit etch selectivity) with respect to the upper and lower channel layers 120a, 120b, allowing for the sacrificial channel layers 321p to be selectively removed in a subsequent operation. In some embodiments, the sacrificial channel layers 321p may include, for example, silicon germanium (e.g., may be silicon germanium layers).

In some embodiments, the upper and lower channel layers 120a, 120b may be formed on a semiconductor substrate 310. The semiconductor substrate 310 may include semiconductor material(s) (e.g., Si, Ge, SiGe, GaP, GaAs, SiC, SiGeC and/or InP). For example, the semiconductor substrate 310 may be provided as a bulk wafer, an epitaxial layer, a silicon-on-insulator (SOI) layer, a semiconductor-on-insulator (SeOI) layer, or the like. Although FIG. 3A illustrates the semiconductor substrate 310 as a single layer, in some embodiments, the semiconductor substrate 310 may include multiple layers (e.g., may include multiple semiconductor layers). In some other embodiments, the upper and lower channel layers 120a, 120b may be formed on the substrate 110 described above with reference to FIGS. 1A-1D.

An isolation region 130 may be formed between the upper channel layers 120a and the lower channel layers 120b. The isolation region 130 may be a spacer that separates (i.e., electrically isolates) the lower channel layers 120b from the upper channel layers 120a. Shallow trench isolation (STI) regions 116 may be formed adjacent to the semiconductor substrate 310 and may be on opposite sides (e.g., in the first direction Y) of the stack of upper and lower channel layers 120a, 120b and sacrificial channel layers 321p.

A sacrificial blocking layer 134p may be formed on the upper and lower channel layers 120a, 120b. The sacrificial blocking layer 134p may be on top of the stack of upper and lower channel layers 120a, 120b and sacrificial channel layers 321p and may also extend on side surfaces of the stack. The sacrificial blocking layer 134p may also be formed on the STI region 116. The sacrificial blocking layer 134p may include, for example, insulating material(s) (e.g., silicon oxide, silicon oxynitride, silicon nitride, silicon carbonitride, silicon boron carbonitride, and/or a low-k material). In some embodiments, the sacrificial blocking layer 134p may include an oxide material (e.g., silicon oxide).

Still referring to FIGS. 3A and 4, a sacrificial gate layer 128p may be formed on the upper and lower channel layers 120a, 120b (Block 410 in FIG. 4). The sacrificial gate layer 128p may surround the stack of upper and lower channel layers 120a, 120b and sacrificial channel layers 321p. For example, the sacrificial gate layer 128p may be on top of the stack of upper and lower channel layers 120a, 120b and sacrificial channel layers 321p and may also extend on side surfaces of the stack. The sacrificial blocking layer 134p may be between the sacrificial gate layer 128p and the stack of upper and lower channel layers 120a, 120b and sacrificial channel layers 321p. In some embodiments, the sacrificial gate layer 128p may include, for example, polysilicon (e.g., may be a polysilicon layer). The sacrificial gate layer 128p may be at least partially replaced with metal in a subsequent operation.

Referring to FIGS. 1A, 1B, 3A, and 4, a pair of lower source/drain regions 140 may be formed on opposing side surfaces of the lower channel layers 120b, respectively, and a pair of upper source/drain regions 150 may be formed on opposing side surfaces of the upper channel layers 120a, respectively (Block 415 in FIG. 4). For example, the lower source/drain regions 140 may be formed by performing an epitaxial growth process using the lower channel layers 120b as a seed layer, and the lower source/drain regions 140 may be epitaxially grown from opposing side surfaces of the lower channel layers 120b (e.g., in the second direction X). Similarly, the upper source/drain regions 150 may be formed by performing an epitaxial growth process using the upper channel layers 120a as a seed layer, and the upper source/drain regions 150 may be epitaxially grown from opposing side surfaces of the upper channel layers 120a (e.g., in the second direction X). In some embodiments, an interlayer insulating layer 152 may be formed on (i.e., surrounding) the lower and upper source/drain regions 140, 150 (see FIG. 1C).

Referring to FIGS. 3B and 4, a trench 340 may be formed in the sacrificial gate layer 128p. (Block 420 in FIG. 4). For example, the trench 340 may be formed through the sacrificial gate layer 128p to separate the sacrificial gate layer 128p into distinct portions (e.g., portions 128p-1, 128p-2) along the first direction Y. As shown in FIG. 3B, the trench 340 may separate the sacrificial gate layer 128p into a first portion 128p-1 and a second portion 128p-2 that are spaced apart in the first direction Y. In some embodiments, the trench 340 may extend into the sacrificial blocking layer 134p and the STI region 116. For example, an etching process (e.g., dry etching and/or wet etching) may be performed to form the trench 340 in the sacrificial gate layer 128p.

The trench 340 may extend adjacent to the stack of upper and lower channel layers 120a, 120b and sacrificial channel layers 321p. For example, the trench 340 may overlap the upper and lower channel layers 120a, 120b in the first direction Y. In some embodiments, the trench 340 may extend lengthwise (i.e., longitudinally) in the second direction X (i.e., into the page in FIG. 3B). For example, the trench 340 may correspond to an area where a gate cut region 132 (see FIG. 1B) is formed in a subsequent operation.

Referring to FIGS. 3C and 4, a contact insulating liner 126 and a contact insulating layer 124 may be formed in the trench 340 (Block 425 in FIG. 4). For example, the contact insulating liner 126 may be formed (e.g., may be conformally formed) in the trench 340 (see FIG. 3B) on inner sidewalls and a lower surface of the trench 340. The contact insulating layer 124 may be formed in the trench 340 on the contact insulating liner 126 and, in some embodiments, may substantially fill a remainder of the trench 340. For example, a deposition process may be used to form (i.e., deposit) the contact insulating liner 126 and the contact insulating layer 124 in the trench 340. The contact insulating liner 126 and the contact insulating layer 124 may comprise the gate cut region 132 described above with reference to FIG. 1B.

Referring to FIGS. 3D and 4, the sacrificial gate layer 128p may be at least partially removed (Block 430 in FIG. 4). For example, the sacrificial gate layer 128p may be selectively removed using a selective etching process (e.g., selective wet etching and/or dry etching).

In some embodiments, the sacrificial gate layer 128p may be partially removed without removing all of the sacrificial gate layer 128p to form a polysilicon layer 128 adjacent to the upper and lower channel layers 120a, 120b (e.g., in the first direction Y). For example, the unremoved portion (i.e., the unstripped portion) of the sacrificial gate layer 128p may form the polysilicon layer 128. The polysilicon layer 128 may be on side surfaces of the upper and lower channel layers 120a, 120b in the first direction Y. For example, the polysilicon layer 128 may be between, in the first direction Y, the contact insulating layer 124 and the upper and lower channel layers 120a, 120b. The polysilicon layer 128 may also be between, in the first direction Y, the contact insulating liner 126 and the upper and lower channel layers 120a, 120b. In some embodiments, the polysilicon layer 128 may be in contact with (e.g., may be directly on) the contact insulating liner 126 and the sacrificial blocking layer 134p. For example, the polysilicon layer 128 may help electrically isolate the upper and lower channel layers 120a, 120b from a contact power rail structure 122 formed in a subsequent operation.

Referring to FIGS. 3E and 4, the sacrificial channel layers 321p may be removed (Block 435 in FIG. 4). For example, the sacrificial channel layers 321p between adjacent ones of the upper channel layers 120a and between adjacent ones of the lower channel layers 120b may be selectively removed, without removing the upper and lower channel layers 120a, 120b. In some embodiments, a selective etching process (e.g., selective wet etching and/or dry etching) may performed to remove the sacrificial channel layers 321p. Spaces (or openings) may be formed between adjacent ones of the upper channel layers 120a and between adjacent ones of the lower channel layers 120b by removing the sacrificial channel layers 321p.

The sacrificial blocking layer 134p may also be at least partially removed. In some embodiments, the sacrificial blocking layer 134p may be partially removed without removing all of the sacrificial blocking layer 134p to form a blocking layer 134 on side surfaces of the upper and lower channel layers 120a, 120b. For example, the unremoved portion (i.e., the unstripped portion) of the sacrificial blocking layer 134p may form the blocking layer 134. For example, the blocking layer 134 may help electrically isolate the upper and lower channel layers 120a, 120b from a contact power rail structure 122 formed in a subsequent operation.

Referring to FIGS. 3F and 4, a first gate structure 170-1 may be formed on the upper and lower channel layers 120a, 120b (Block 440 in FIG. 4). In some embodiments, forming the first gate structure 170-1 may include forming an upper gate structure 170a on the upper channel layers 120a and forming a lower gate structure 170b on the lower channel layers 120b. For example, forming the upper and lower gate structures 170a, 170b may include forming a gate insulator 172 on the upper and lower channel layers 120a, 120b, and forming upper and lower conductive gates 174a, 174b on the gate insulator 172. In some embodiments, the gate insulator 172 may also be formed on the semiconductor substrate 310 and the STI region 116.

As described above, forming the first gate structure 170-1 may include forming the sacrificial gate layer 128p, and subsequently replacing at least a portion of the sacrificial gate layer 128p with metal conductive gates 174a, 174b. The first gate structure 170-1 may thus be formed using a replacement metal gate (RMG) process. In some embodiments, a second gate structure 170-2 may also be formed using an RMG process, as shown in FIG. 3F. For example, the first gate structure 170-1 and the second gate structure 170-2 may be adjacent to each other in the first direction Y, and may be separated from each other in the first direction Y by the contact insulating layer 124 and the contact insulating liner 126.

As shown in FIG. 3F, the upper gate structure 170a may surround the upper channel layers 120a, and the lower gate structure 170b may surround the lower channel layers 120b. For example, the upper conductive gate 174a may extend on an upper surface, a lower surface, and a side surface of each upper channel layer 120a. The lower conductive gate 174b may extend on an upper surface, a lower surface, and a side surface of each lower channel layer 120b. In some embodiments, the upper and lower conductive gates 174a, 174b may be formed by depositing one or more conductive layers (e.g., a metal layer and/or work function layer(s)), with an upper portion thereof forming the upper conductive gate 174a and a lower portion thereof forming the lower conductive gate 174b. For example, the upper and lower conductive gates 174a, 174b may be integrated in a monolithic or unitary structure, that is, a structure formed by the same process or the same series of processes (e.g., without a structurally or visibly separate interface therebetween), although embodiments are not limited thereto. As such, the upper and lower conductive gates 174a, 174b may have a common interface 174_I in some embodiments (shown by a dashed line in FIG. 3F).

Referring to FIGS. 3G and 4, a contact power rail structure 122 may be formed in the contact insulating layer 124 (Block 445 in FIG. 4). For example, the contact power rail structure 122 may extend into the contact insulating layer 124. In some embodiments, the contact power rail structure 122 also extends into a lower portion of the contact insulating liner 126. The contact power rail structure 122 may extend (i.e., may longitudinally extend) in the second direction X (see FIG. 1B) and may overlap the upper and lower channel layers 120a, 120b in the first direction Y.

In some embodiments, forming the contact power rail structure 122 may include forming a trench (or opening) in the contact insulating layer 124, and forming the contact power rail structure 122 in the trench. For example, an etching process (e.g., dry etching and/or wet etching) may be performed to form the trench in the contact insulating layer 124, and a deposition process may be used to form (i.e., deposit) the contact power rail structure 122 in the trench within the contact insulating layer 124.

As shown in FIG. 3G, the contact power rail structure 122 may overlap the upper and lower gate structures 170a, 170b in the first direction Y. The contact insulating layer 124 and the contact insulating liner 126 may be on opposing side surfaces of the contact power rail structure 122 in the first direction Y. For example, the contact insulating layer 124 and the contact insulating liner 126 may help electrically isolate the contact power rail structure 122 from the upper and lower gate structures 170a, 170b (e.g., from the upper and lower conductive gates 174a, 174b). The polysilicon layer 128 and the blocking layer 134 may be between the contact power rail structure 122 and the upper and lower channel layers 120a, 120b in the first direction Y. For example, the polysilicon layer 128 and the blocking layer 134 may help electrically isolate the contact power rail structure 122 from the upper and lower channel layers 120a, 120b.

Referring to FIG. 4 and back to FIGS. 1B, 1C, and 1D, an upper source/drain contact 156 may be formed on the upper source/drain region 150 and the contact power rail structure 122 (Block 450 in FIG. 4). The upper source/drain contact 156 may be electrically connected to the upper source/drain region 150 and the contact power rail structure 122. For example, the upper source/drain contact 156 may be formed during the middle-of-line (MOL) portion of device fabrication.

In some embodiments, an upper gate contact 178 may be formed on the upper and lower gate structures 170a, 170b. For example, the upper gate contact 178 may be formed during the middle-of-line (MOL) portion of device fabrication.

An upper structure 138 may be formed on the upper and lower transistors Ta, Tb. For example, the upper structure 138 may include elements formed during the middle-of-line (MOL) portion and/or the back-end-of-line (BEOL) portion of device fabrication. The upper structure 138 may include conductive elements (e.g., wire(s) and/or via plug(s)) and insulating elements (e.g., interlayer insulating layer(s) and/or spacer(s)).

In some embodiments, the semiconductor substrate 310 may be at least partially removed and replaced with the substrate 110. For example, the semiconductor substrate 310 may be selectively removed using a selective etching process (e.g., selective wet etching and/or dry etching). A backside contact structure 148 may be formed in the substrate 110 and on a lower surface of the lower source/drain region 140. For example, the backside contact structure 148 may extend into the substrate 110 to be in contact with (e.g., to be in electrical contact with) the lower source/drain region 140.

Still referring to FIGS. 1B, 1C, 1D, and 4, a BSPDN structure 142 may be formed on a second surface S2 (i.e., a backside) of the substrate 110 (Block 455 in FIG. 4). For example, the BSPDN structure 142 may be formed on lower surfaces of the lower source/drain regions 140. The BSPDN structure 142 may include a backside insulator 146 and a plurality of backside power rails 144 formed in the backside insulator 146.

In some embodiments, forming the BSPDN structure 142 may include forming a first backside power rail 144 on a lower surface of the contact power rail structure 122. Further, in some embodiments, forming the BSPDN structure 142 may include forming a second backside power rail 144 on a lower surface of the backside contact structure 148. For example, the second backside power rail 144 may be adjacent to the first backside power rail 144 (e.g., in the first direction Y). The contact power rail structure 122 may electrically connect the upper source/drain region 150 of the upper transistor Ta to the first backside power rail 144, as shown in FIG. 1C. Further, the backside contact structure 148 may electrically connect the lower source/drain region 140 of the lower transistor Tb to the second backside power rail 144, as shown in FIG. 1C. Accordingly, the integrated circuit device 100 shown in FIGS. 1B-1D may be formed.

As shown in FIG. 1B, the contact power rail structure 122 may have a line (or rail) shape in a plan view. The line (or rail) shape may increase the width and cross-sectional area of the contact power rail structure 122, as well as its contact area with the backside power rail 144 and the upper source/drain contact 156. As such, the configuration of the contact power rail structure 122 may advantageously reduce contact resistance with the backside power rail 144 and the upper source/drain contact 156, mitigate current crowding by distributing current more uniformly across a larger area, and reduce a voltage drop during backside power delivery to the upper source/drain region 150 of the upper transistor Ta. Accordingly, the performance and reliability of the integrated circuit device 100 may be improved. The configuration of the contact power rail structure 122 may also provide design flexibility for the backside power rail 144, enabling optimized power delivery for the BSPDN structure 142 and/or enhanced layout efficiency for the integrated circuit device 100.

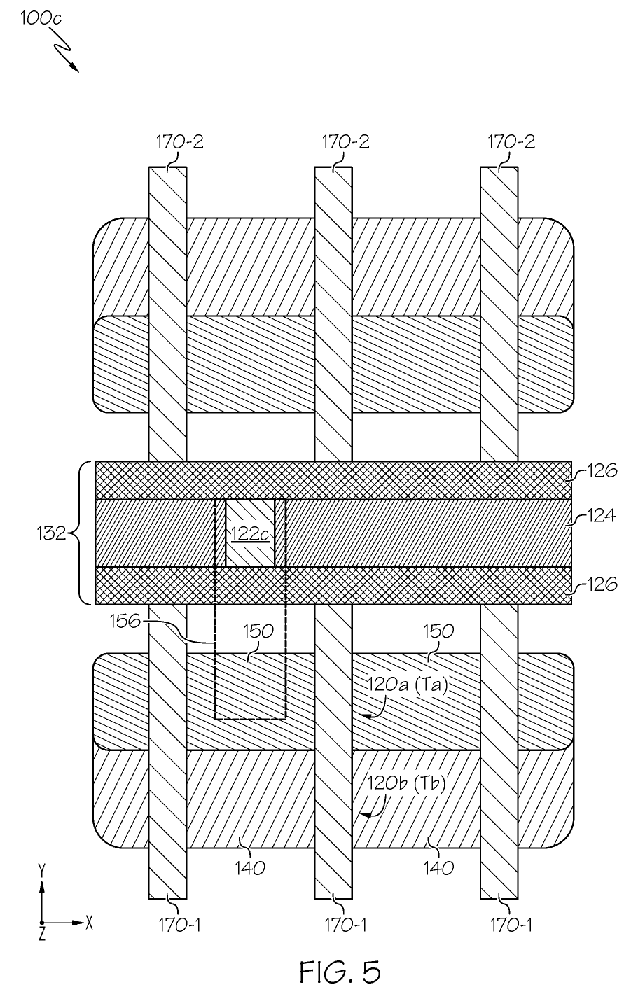

FIG. 5 is a schematic plan (or layout) view illustrating an integrated circuit device according to a comparative example. Repeated description of like elements described above may be omitted for ease of description.

Referring to FIG. 5, an integrated circuit device 100c may include a contact power structure 122c that has a square shape in a plan view. For example, the contact power structure 122c may be similar to a via, with a relatively tall height (or thickness) in the third direction Z and a relatively narrow width in the second direction X, resulting in a relatively high aspect ratio for the contact power structure 122c. The square shape may reduce the width and cross-sectional area of the contact power structure 122c, as well as its contact area with a backside power rail (not shown) and an upper source/drain contact 156. As such, the configuration of the contact power structure 122c may result in higher contact resistance with the backside power rail and the upper source/drain contact 156, and may also lead to increased current crowding and a higher voltage drop during backside power delivery.

Unless otherwise defined, all terms used herein have the same meaning as commonly understood by one of ordinary skill in the art. Further, all terms should be interpreted as having a meaning that is consistent with their meaning in the context of the relevant art and this disclosure and will not be interpreted in an idealized or overly formal sense unless expressly so defined herein.

In the description above, example embodiments may be described with reference to regions of particular conductivity types. It will be appreciated that opposite conductivity type devices may be formed by simply reversing the conductivity of the n-type and p-type layers in each of the above embodiments. Thus, it will be appreciated that the present disclosure covers both n-channel and p-channel devices for each different device structure.

The terminology used herein is for the purpose of describing particular embodiments only and is not intended to be limiting of embodiments. The singular forms “a,” “an,” and “the” are intended to include the plural forms as well, unless the context clearly indicates otherwise. The terms “comprises,” “comprising,” “includes” and/or “including” specify the presence of the stated features, steps, operations, elements, components and/or groups, but do not preclude the presence or addition of one or more other features, steps, operations, elements, components and/or groups thereof.

It will be understood that, although the terms “first,” “second,”, “third,” etc. may be used throughout this specification to describe various elements, these elements should not be limited by these terms. Rather, these terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terms “surround” or “cover” or “fill” as used herein may not require completely surrounding or covering or filling the described elements or layers, but may, for example, refer to partially surrounding or covering or filling the described elements or layers. Components or layers described with reference to “overlap” in a particular direction may be at least partially obstructed by one another when viewed along a line extending in the particular direction or in a plane perpendicular to the particular direction.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. The term “connected” may include physical and/or electrical connections.

Spatially relative terms such as “below” or “above” or “upper” or “lower” or “top” or “bottom” or “side” may be used herein to describe a relationship of one element, layer or region to another element, layer or region based on a frame of reference (e.g., a substrate), as illustrated in the figures. It will be understood that these terms are intended to encompass different orientations of the device in addition to the orientation depicted in the figures.

Example embodiments are described herein with reference to the accompanying drawings, which may include cross-section illustrations that are schematic illustrations of idealized embodiments (and intermediate structures). Many different forms and embodiments are possible without deviating from the teachings of this disclosure. Accordingly, the present disclosure should not be construed as limited to the example embodiments set forth herein. As such, it will be understood by those of ordinary skill in the art that various changes in form and details may be made therein without departing from the scope as defined herein. In the drawings, the sizes and relative sizes of layers and regions may be exaggerated for clarity. Additionally, variations from the shapes of the illustrations as a result, for example, of manufacturing techniques and/or tolerances, are to be expected.

Embodiments of the present disclosure are also described with reference to fabrication operations and flowchart diagrams. It will be appreciated that the steps shown in the fabrication operations and flowchart diagrams need not be performed in the order shown.

The above-disclosed subject matter is to be considered illustrative, and not restrictive, and the appended claims are intended to cover all such modifications, enhancements, and other embodiments, which fall within the scope of the present disclosure. Thus, to the maximum extent allowed by law, the scope is to be determined by the broadest permissible interpretation of the following claims and their equivalents, and shall not be restricted or limited by the foregoing detailed description.

1. An integrated circuit device, comprising:
a substrate;
a lower transistor on a first surface of the substrate;
an upper transistor on the lower transistor, the upper transistor comprising an upper gate structure extending in a first lateral direction parallel to the first surface of the substrate and an upper source/drain region adjacent to the upper gate structure in a second lateral direction orthogonal to the first lateral direction;
a backside power delivery network (BSPDN) structure on a second surface of the substrate opposite the first surface, the BSPDN structure comprising a backside power rail; and
a contact power rail structure that electrically connects the upper source/drain region to the backside power rail,
wherein the contact power rail structure overlaps the upper gate structure in the first lateral direction.

2. The integrated circuit device of claim 1, further comprising a contact insulating layer on opposing side surfaces of the contact power rail structure in the first lateral direction,
wherein the contact insulating layer is between the contact power rail structure and the upper gate structure in the first lateral direction.

3. The integrated circuit device of claim 2, further comprising a contact insulating liner on the opposing side surfaces of the contact power rail structure in the first lateral direction,
wherein the contact insulating layer is between the contact power rail structure and the contact insulating liner in the first lateral direction.

4. The integrated circuit device of claim 3, wherein the contact insulating layer comprises a first insulating material, and the contact insulating liner comprises a second insulating material that is different from the first insulating material.

5. The integrated circuit device of claim 1, further comprising a gate cut region that separates adjacent gate structures in the first lateral direction,
wherein the contact power rail structure extends in the gate cut region.

6. The integrated circuit device of claim 5, wherein the gate cut region comprises:
a contact insulating layer on opposing side surfaces of the contact power rail structure in the first lateral direction; and
a contact insulating liner on the opposing side surfaces of the contact power rail structure in the first lateral direction, with the contact insulating layer therebetween.

7. The integrated circuit device of claim 1, wherein the upper gate structure is included in a first gate structure, and
wherein the integrated circuit device further comprises a second gate structure spaced apart from the first gate structure in the first lateral direction, with the contact power rail structure therebetween.

8. The integrated circuit device of claim 1, further comprising a polysilicon layer between the contact power rail structure and the upper gate structure in the first lateral direction,
wherein the upper gate structure comprises a metal material.

9. The integrated circuit device of claim 1, wherein the backside power rail is a first backside power rail,
wherein the BSPDN structure further comprises a second backside power rail adjacent to the first backside power rail,
wherein the lower transistor comprises a lower source/drain region, and
wherein the integrated circuit device further comprises a backside contact structure that extends into the substrate and electrically connects the lower source/drain region to the second backside power rail.

10. The integrated circuit device of claim 1, wherein the lower transistor comprises a lower gate structure extending in the first lateral direction and a lower source/drain region adjacent to the lower gate structure in the second lateral direction, and
wherein the contact power rail structure overlaps the lower gate structure in the first lateral direction.

11. The integrated circuit device of claim 1, wherein the backside power rail extends continuously on a lower surface of the contact power rail structure in the second lateral direction.

12. The integrated circuit device of claim 1, wherein the backside power rail extends discontinuously on a lower surface of the contact power rail structure, and
wherein the backside power rail comprises:
a first portion electrically connected to the contact power rail structure; and
a second portion electrically connected to the contact power rail structure and spaced apart from the first portion in the second lateral direction.

13. The integrated circuit device of claim 1, further comprising an upper source/drain contact on the upper source/drain region,
wherein the upper source/drain contact is electrically connected to the upper source/drain region and the contact power rail structure.

14. An integrated circuit device, comprising:
a substrate;
a lower transistor on a first surface of the substrate;
an upper transistor on the lower transistor, the upper transistor comprising an upper gate structure extending in a first lateral direction parallel to the first surface of the substrate and an upper source/drain region adjacent to the upper gate structure in a second lateral direction orthogonal to the first lateral direction;
a backside power delivery network (BSPDN) structure on a second surface of the substrate opposite the first surface, the BSPDN structure comprising a backside power rail; and
a contact power rail structure that electrically connects the upper source/drain region to the backside power rail,
wherein a width of the contact power rail structure in the second lateral direction is greater than a width of the upper source/drain region in the second lateral direction.

15. The integrated circuit device of claim 14, further comprising a gate cut region that separates adjacent gate structures in the first lateral direction,
wherein the contact power rail structure extends in the gate cut region, and
wherein the gate cut region comprises a contact insulating layer between the contact power rail structure and the upper gate structure in the first lateral direction.

16. A method of forming an integrated circuit device, the method comprising:
forming a lower channel layer and an upper channel layer, the lower and upper channel layers spaced apart in a vertical direction;
forming a lower source/drain region on a side surface of the lower channel layer and an upper source/drain region on a side surface of the upper channel layer;
forming a contact power rail structure that overlaps at least one of the lower channel layer or the upper channel layer in a first lateral direction orthogonal to the vertical direction; and
forming a backside power delivery network (BSPDN) structure comprising a backside power rail on a lower surface of the contact power rail structure,
wherein the contact power rail structure electrically connects the upper source/drain region to the backside power rail.

17. The method of claim 16, further comprising:
forming a sacrificial gate layer at least partially surrounding the lower and upper channel layers; and
partially removing the sacrificial gate layer without removing all of the sacrificial gate layer to form a polysilicon layer adjacent to the lower and upper channel layers,
wherein the polysilicon layer is between the contact power rail structure and the lower and upper channel layers in the first lateral direction.

18. The method of claim 16, further comprising:
forming a sacrificial gate layer at least partially surrounding the lower and upper channel layers;
forming a trench in the sacrificial gate layer;
forming a contact insulating liner on inner sidewalls and a lower surface of the trench; and
forming a contact insulating layer in the trench and on the contact insulating liner,
wherein forming the contact power rail structure comprises forming the contact power rail structure in the contact insulating layer, and
wherein the contact insulating liner and the contact insulating layer are on opposing side surfaces of the contact power rail structure in the first lateral direction.

19. The method of claim 16, further comprising:
forming a sacrificial gate layer at least partially surrounding the lower and upper channel layers;
forming a trench through the sacrificial gate layer to separate the sacrificial gate layer into distinct portions along the first lateral direction; and
forming a contact insulating layer in the trench,
wherein the contact power rail structure extends into the contact insulating layer.

20. The method of claim 19, further comprising:
at least partially removing the sacrificial gate layer; and
forming a gate structure on the lower and upper channel layers, the gate structure comprising a lower gate structure at least partially surrounding the lower channel layer and an upper gate structure at least partially surrounding the upper channel layer,
wherein the contact power rail structure overlaps the lower and upper gate structures in the first lateral direction.
